(19) United States
(12) Patent Application Publication
(10) Pub. No.: US 2013/0256015 A1
(43) Pub. Date: Oct. 3, 2013

(54) CELLULOSIC PRINTED CIRCUIT BOARD MATERIALS HAVING BORONATE MOIETIES

(71) Applicants: William B. Carlson, Seattle, WA (US); Gregory D. Phelan, Cortland, NY (US)

(72) Inventors: William B. Carlson, Seattle, WA (US); Gregory D. Phelan, Cortland, NY (US)

(73) Assignee: Empire Technology Developement LLC

(21) Appl. No.: 13/701,892

(22) PCT Filed: Mar. 29, 2012
(86) PCT No.: PCT/US12/31226

§ 371 Date: Dec. 4, 2012

(51) Int. Cl. H05K 1/03

(52) U.S. Cl. CPC H05K 1/0353
USPC 174/258; 524/35; 536/56; 106/163.01

(57) ABSTRACT

A printed circuit board is provided here, the printed circuit board including a cellulosic polymer, where the cellulosic polymer contains a boronate moiety.

### FIELD

The technology provided herein is generally related to printed circuit boards that include a cellulosic polymer having boronate moieties, as well as methods of making such printed circuit boards.

### BACKGROUND

The following description is provided to assist the understanding of the reader. None of the information provided or references cited is admitted to be prior art.

An unintended consequence of the information technology age has been a substantial growth in toxic waste. It is estimated that about 100 million personal computers are discarded worldwide every year. In the United States, about two million tons of computer-related waste is generated per year. The European Union has identified waste electrical and electronic equipment as its fastest growing waste stream, which amounts to approximately 5% of all municipal solid waste, and continues to grow at three times the rate of the total solid waste stream.

A particularly toxic component of electronic waste include the brominated bisphenol-A epoxy (BPA) resins. In fact, these resins are so toxic that in some municipalities they must be separated from bulk electronic waste prior to disposal. The BPA resins in general, including the brominated BPA analogs, are endocrine toxins. In 2008, several governments questioned the safety of BPAs, prompting some retailers to withdraw polycarbonate products. A January 2010 report from the United States Food and Drug Administration (FDA), “Update on Bisphenol A for Use in Food Contact Applications,” raised further concerns regarding the exposure of fetuses, infants, and young children to BPAs. In September of 2010, Canada became the first country to declare BPA a toxic substance.

Nonetheless, the brominated BPA resins are still incorporated as fire retardants into electronic devices such as printed circuit boards (PCBs). These resins remain widely used as fire retardants because electronic devices pose a significant risk of catching fire. Unfortunately, brominated BPA is particularly difficult to destroy; it is resistant to incineration and releases toxic chemicals into the atmosphere upon pyrolysis at high temperatures.

The rate at which brominated BPA resins enter the waste stream is increasing. Historically, durable electronic goods, such as televisions, radios, and stereos took approximately five to twenty years to enter the waste stream. Currently, however, items with logic, memory, and complex printed circuit boards have an increasingly high turnover rate and thus enter the waste stream much more quickly. For example, electronics such as cell phones, portable music players, or gaming consoles, often become obsolete and enter the waste stream within one to three years.

Once incorporated into electronic devices, brominated BPA resins are particularly difficult to reclaim before they enter the waste stream and reach landfills where they can leach into the environment. This is so because electronic waste management is relatively complex. For example, electronic waste contains useful materials (e.g., recyclable metals, glasses, and plastics), valuable metals (e.g., Au, Cu, Ni, Pd, Ag, and Zn), toxic metals (e.g., Pb, Hg, Cr, Cd), and toxic organic and inorganic compounds. As such, the processing of such electronic waste is complicated, expensive, and potentially hazardous. Safe and efficient separation of electronic waste components from the other waste remains a challenge.

Accordingly, environmentally friendly replacements for brominated BPA resins, made from improved fire retardants, are needed to preempt the use of this endocrine toxin in electronic devices, such as printed circuit boards, and thus reduce the impact of brominated BPA resins on the environment when these electronic devices are discarded.

### SUMMARY

In one aspect, a printed circuit board (“PCB”) is provided. The printed circuit board includes a cellulosic polymer, which contains a boronate moiety. In some embodiments, the cellulosic polymer includes paper, cotton, cloth, fabric, parchment, hanji, washi, hemp, bamboo, rice, or starch. In some embodiments, the cellulosic polymer including a boronate moiety contains one or more glucose monomers of Formula I, II, III, IV, V, VI, or VII:

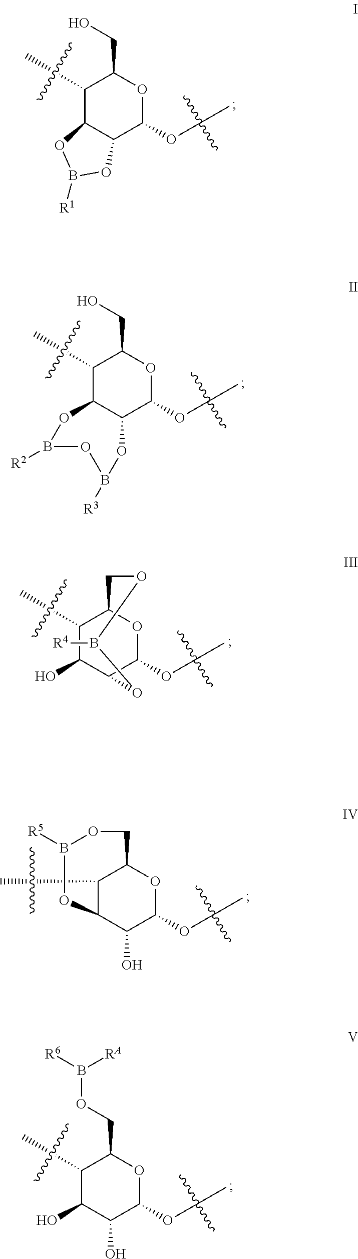

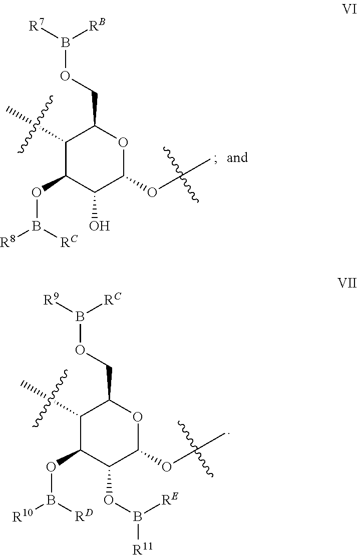

In the above Formulas, R¹-R¹¹ are each independently alkyl, alkenyl, cycloalkyl, heterocycloalkyl, aryl or heteroaryl; and where R^{A}-R^{E} are each independently OH, O-alkyl, O-alkenyl, O-aryl or O-heteroaryl. In some embodiments, R¹-R¹¹ are each independently C₁-C₈ alkyl, C₁-C₈ alkenyl, C₆ aryl, or C₅-C₁₀ heteroaryl. In some embodiments, R¹-R¹¹ are each independently C₁-C₄ alkyl. In some embodiments, R¹-R¹¹ are each independently methyl, ethyl, n-propyl, iso-propyl, n-butyl, iso-butyl, tert-butyl, ethenyl, propenyl, 1-butenyl, 2-butenyl, phenyl, tolyl, furan-2-yl, thiophen-2-yl, bromomethyl, bromoethyl, chloromethyl, chloroethyl, iodomethyl, iodoethyl, chlorobromomethyl, chlorobromoethyl, methylsulfanylmethyl, or methyl mercaptan. In some embodiments, R^{A}-R^{E} are each OH.

In any of the above embodiments, the printed circuit board has a first surface, a second surface, and an interior, wherein the first surface, second surface, or both the first surface and second surface, include the boronate moiety, and the interior does not include the boronate moiety. In any of the embodiments, the printed circuit board is substantially free of a brominated BPA resin.

In another aspect, a composition is provided where the composition includes a cellulosic polymer having one or more glucose monomers of Formula I, II, III, IV, V, VI, or VII, as shown above. In certain embodiments, the composition is a thermoplastic.

In any of the above the embodiments, the cellulose polymer includes glucose monomers where up to 50% of the glucose monomers of the cellulose polymer include a boronate moiety. In any of the above the embodiments, the cellulose polymer may include glucose monomers where at least 50% of the glucose monomers of the cellulose polymer include a boronate moiety. In some embodiments, less than 40% of the hydroxyl groups of the cellulose polymer comprise a boronate moiety. In other embodiments, about 40% to about 60% of the hydroxyl groups of the cellulose polymer comprise a boronate moiety. In some embodiments, at least 60% of the hydroxyl groups of the cellulose polymer comprise a boronate moiety. In any of the above embodiments, the printed circuit board may be biodegradable.

In another aspect, a method of making an article is provided, the method including: providing a non-thermoplastic cellulosic material including a first boronate moiety; and contacting the non-thermoplastic cellulosic material with a thermoplastic cellulosic polymer including a second boronate moiety. In certain embodiments, the first and second boronate moiety are provided in glucose monomers of Formula I, II, III, IV, V, VI, or VII, as shown above. In certain embodiments, the non-thermoplastic cellulosic material comprises paper. In some embodiments, at least some of the non-thermoplastic cellulosic material is infused with the thermoplastic cellulosic polymer. In certain embodiments, the method further comprises heating and pressurizing the non-thermoplastic cellulosic material and the thermoplastic cellulosic polymer. In some embodiments, the method further comprises printing a metallic conductor onto a surface of the article to form a printed circuit board. In certain embodiments, the method further comprises fusing together a plurality of the articles to make a laminated structure printed circuit board.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

FIG. 1 is a schematic illustration of a process of boronating paper fiber, according to various embodiments.

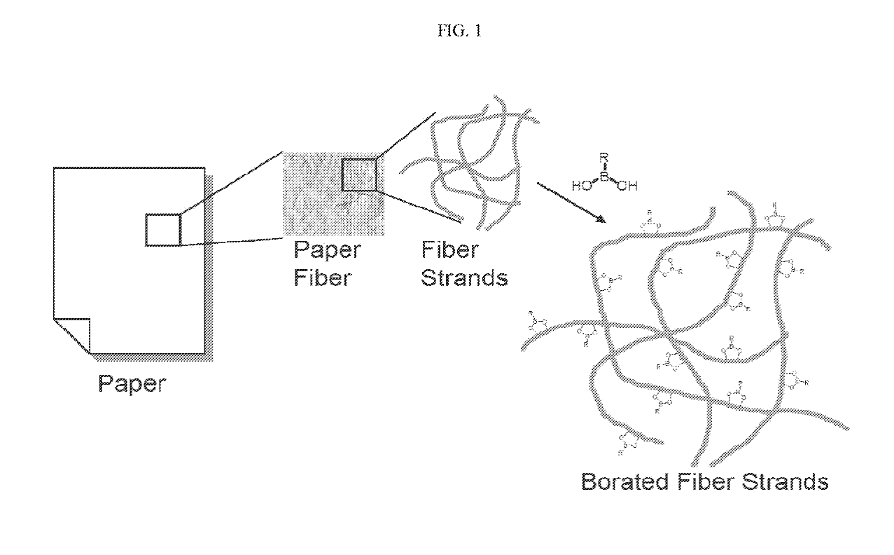

FIG. 2 illustrates a process of constructing a motherboard out of boronated cellulose materials, according to an embodiment.

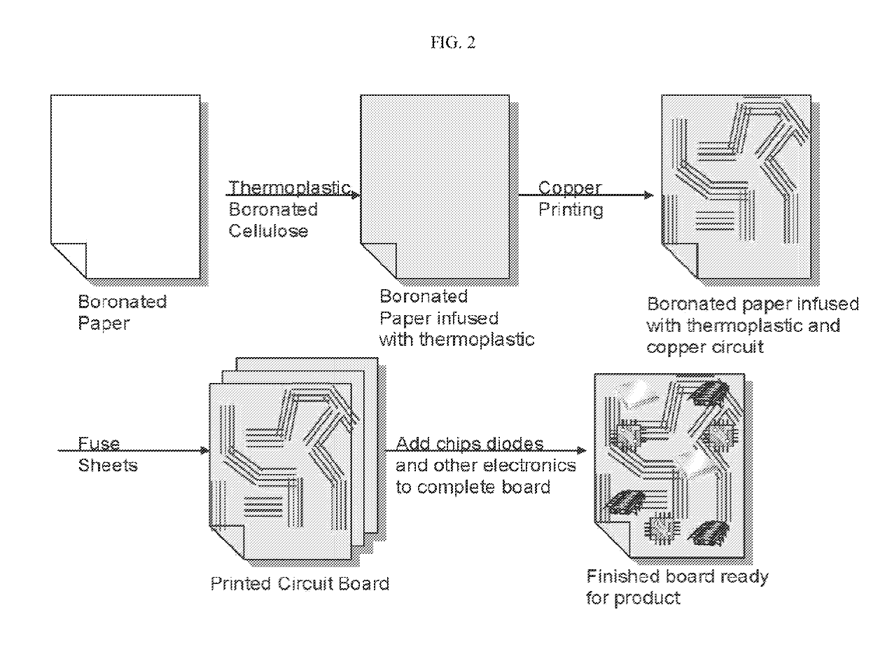

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

The technology is described herein using several definitions, as set forth throughout the specification.

The use of the terms “a” and “an” and “the” and similar referents in the context of describing the elements (especially in the context of the following claims) are to be construed to cover both the singular and the plural, unless otherwise indicated herein or clearly contradicted by context.

As used herein, “substantially” and “about” will be understood by persons of ordinary skill in the art and will vary to some extent depending upon the context in which it is used. If there are uses of the terms which are not clear to persons of ordinary skill in the art, given the context in which it is used, “about” and “substantially” will mean up to plus or minus 10% of the particular term—e.g., less than or equal to ±5%, less than or equal to ±2%, less than or equal to ±1%, less than or equal to ±0.5%, less than or equal to ±0.2%, less than or equal to ±0.1%, less than or equal to ±0.05%.

Alkyl moieties include straight chain and branched chain alkyl moieties which may be substituted or unsubstituted. In some embodiments, an alkyl moiety has from 1 to 30 carbon atoms, from 1 to 24 carbons, from 1 to 18 carbons, from 1 to 12 carbons, from 1 to 8 carbons or, in some embodiments, from 1 to 6, or 1, 2, 3, 4 or 5 carbon atoms. Examples of straight chain alkyl moieties include moieties such as methyl, ethyl, n-propyl, n-butyl, n-pentyl, n-hexyl, n-heptyl, and n-octyl moieties. Examples of branched alkyl moieties include, but are not limited to, isopropyl, iso-butyl, sec-butyl, tert-butyl, neopentyl, isopentyl, and 2,2-dimethylpropyl moieties.

Cycloalkyl moieties are cyclic alkyl moieties. In some embodiments, cycloalkyl moieties have from 3 to 30 carbon atoms. In some embodiments, the cycloalkyl moiety has 3 to 10 or 3 to 7 ring members, whereas in other embodiments the number of ring carbon atoms range from 3 to 5, 3 to 6, or 5, 6 or 7. Cycloalkyl moieties further include monocyclic, bicyclic and polycyclic ring systems. Monocyclic moieties include, e.g., cyclopropyl, cyclobutyl, cyclopentyl, cyclohexyl, and cycloheptyl moieties. Bicyclic and polycyclic cycloalkyl moieties include bridged or fused rings, such as, but not limited to, bicyclo[3.2.1]octane, decalinyl, and the like. Cycloalkyl moieties include rings that are substituted with straight or branched chain alkyl moieties. In some embodiments, the cycloalkyl moieties are substituted cycloalkyl moieties. Representative substituted alkyl moieties may be mono-substituted or substituted more than once, such as, but not limited to, mono-, di- or tri-substituted with substituents such as those listed herein.

Heterocycloalkyl groups refer to a single aliphatic ring, usually with 3 to 7 ring atoms, containing at least 2 carbon atoms in addition to 1-3 heteroatoms independently selected from oxygen, sulfur, and nitrogen, as well as combinations comprising at least one of the foregoing heteroatoms. Heterocycloalkyl groups also refers to 5- and 6-membered carbocyclic aromatic rings fused to a 5- to 7-membered heterocycloalkyl ring containing 1 or more heteroatoms chosen from N, O, and S, provided that the point of attachment is at the heterocycloalkyl ring. Suitable heterocycloalkyl groups include, for example (as numbered from the linkage position assigned priority 1), 2-pyrrolinyl, 2,4-imidazolidinyl, 2,3-pyrazolidinyl, 2-piperidyl, 3-piperidyl, 4-piperidyl, and 2,5-piperzinyl. Morpholinyl groups are also contemplated, including 2-morpholinyl and 3-morpholinyl (numbered wherein the oxygen is assigned priority 1). Substituted heterocycloalkyl also includes ring systems substituted with one or more oxo moieties, such as piperidinyl N-oxide, morpholinyl-N-oxide, 1-oxo-1-thiomorpholinyl and 1,1-dioxo-1-thiomorpholinyl.

Alkenyl moieties include straight and branched chain alkyl moieties as defined above, except that at least one double bond exists between two carbon atoms. In some embodiments, alkenyl moieties have from 2 to 30 carbon atoms, and typically from 2 to 10 carbons or, in some embodiments, from 2 to 8, 2 to 6, or 2 to 4 carbon atoms. Examples include, but are not limited to vinyl, allyl, —CH═CH(CH₃), —CH═C(CH₃)₂, —C(CH₃)═CH₂, —C(CH₃)═CH(CH₃), —C(CH₂CH₃)═CH₂, among others. Representative substituted alkenyl moieties may be mono-substituted or substituted more than once, such as, but not limited to, mono-, di- or tri-substituted with substituents such as those listed herein.

Alkynyl moieties include straight and branched chain alkyl moieties as defined above, except that at least one triple bond exists between two carbon atoms. In some embodiments, alkynyl moieties have from 2 to 30 carbon atoms, and typically from 2 to 10 carbon atoms or, in some embodiments, from 2 to 8, 2 to 6, or 2 to 4 carbon atoms. Examples include, but are not limited to —C≡CH, —C≡CCH₃, —CH₂C≡CH, —CH(CH₃)C≡CH, —CH₂C≡CCH₃, —CH(CH₂CH₃)C≡CH, among others. Representative substituted alkynyl moieties may be mono-substituted or substituted more than once, such as, but not limited to, mono-, di- or tri-substituted with substituents such as those listed herein.

Aryl moieties are cyclic aromatic hydrocarbons of 6 to 14 carbons that do not contain heteroatoms. Aryl moieties herein include monocyclic, bicyclic and tricyclic ring systems. Thus, aryl moieties include, but are not limited to, phenyl, azulenyl, heptalenyl, biphenyl, fluorenyl, phenanthrenyl, anthracenyl, indenyl, indanyl, pentalenyl, and naphthyl moieties. In some embodiments, aryl moieties contain from 6 to 12 or even 6 to 10 carbon atoms in the ring portions of the moieties. In some embodiments, the aryl moieties are phenyl or naphthyl. The phrase “aryl moieties” includes moieties containing fused rings, such as fused aromatic-aliphatic ring systems (e.g., indanyl, tetrahydronaphthyl, and the like). Aryl moieties may be unsubstituted, monosubstituted, or substituted more than once with substituents such as those indicated herein.

Heteroaryl groups include an aromatic ring containing, for example, 5 to 12, or 5 to 10 atoms including one or more heteroatoms (e.g., 1, 2, 3 or 4 heteroatoms) selected from N, O, S, P, and As and with the remaining ring atoms being carbon. Heteroaryl groups do not contain adjacent N, O, S, P, and As atoms. Unless otherwise indicated, heteroaryl groups may be bound to the parent structure by a carbon or nitrogen atom, as valency permits. For example, “pyridyl” includes 2-pyridyl, 3-pyridyl and 4-pyridyl groups, and “pyrrolyl” includes 1-pyrrolyl, 2-pyrrolyl and 3-pyrrolyl groups. Heteroaryl groups may be monocyclic or polycyclic (e.g., bicyclic, tricyclic). In some embodiments, a heteroaryl group is monocyclic. Examples include pyrrole, pyrazole, imidazole, triazole (e.g., 1,2,3-triazole, 1,2,4-triazole, 1,2,4-triazole), tetrazole, furan, isoxazole, oxazole, oxadiazole (e.g., 1,2,3-oxadiazole, 1,2,4-oxadiazole, 1,3,4-oxadiazole), thiophene, isothiazole, thiazole, thiadiazole (e.g., 1,2,3-thiadiazole, 1,2,4-thiadiazole, 1,3,4-thiadiazole), pyridine, pyridazine, pyrimidine, pyrazine, triazine (e.g., 1,2,4-triazine, 1,3,5-triazine) and tetrazine. In some embodiments, more than one ring of a polycyclic heteroaryl group are aromatic. Examples include indole, isoindole, indazole, benzoimidazole, benzotriazole, benzofuran, and benzoxazole.

Alkoxy moieties are hydroxyl moieties (—OH) in which the bond to the hydrogen atom is replaced by a bond to a carbon atom of an alkyl moiety as defined above. Examples of linear alkoxy moieties include but are not limited to methoxy, ethoxy, propoxy, butoxy, pentoxy, hexoxy, and the like. Examples of branched alkoxy moieties include but are not limited to isopropoxy, sec-butoxy, tert-butoxy, isopentoxy, isohexoxy, and the like. Representative substituted alkoxy moieties may be substituted one or more times with substituents such as those indicated herein.

The term “amine” (or “amino”) as used herein refers to —NHR and —NRR′ moieties, wherein R, and R′ are independently hydrogen, or a substituted or unsubstituted alkyl, alkenyl, alkynyl, cycloalkyl, or, aryl moiety as defined herein. Examples of amino moieties include —NH₂, methylamino, dimethylamino, ethylamino, diethylamino, propylamino, isopropylamino, phenylamino, benzylamino, and the like.

The term “hydroxyl” refers to —OH moieties.

The term “halo” or “halogen” refers to —F, —Cl, —Br, and —I moieties.

The term “acyl” refers to —C(O)R moieties, where R is a substituted or unsubstituted alkyl, cycloalkyl, alkenyl, alkynyl, or aryl moiety as defined herein.

“Substituted” refers to a chemical moiety as described herein that further includes one or more substituents, such as lower alkyl (including substituted lower alkyl such as haloalkyl, hydroxyalkyl, aminoalkyl), aryl (including substituted aryl), acyl, halogen, hydroxy, amino, alkoxy, alkylamino, acylamino, thioamido, acyloxy, aryloxy, aryloxyalkyl, carboxy, thiol, sulfide, sulfonyl, oxo, both saturated and unsaturated cyclic hydrocarbons (e.g., cycloalkyl, cycloalkenyl), cycloheteroalkyls and the like. These moieties may be attached to any carbon or substituent of the alkyl, alkenyl, alkynyl, aryl, cycloheteroalkyl, alkylene, alkenylene, alkynylene, arylene, or hetero moieties. Additionally, the substituents may be pendent from, or integral to, the carbon chain itself.

The terms “borated” or “boronated” refer interchangeably to substrates having one or more boronic acid ester derivatives (i.e., “boronate moieties”),

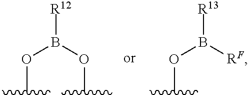

where R¹² and R¹³ are independently alkyl, alkenyl, aryl or heteroaryl, and where R^{F} is OH, O-alkyl, O-alkenyl, O-aryl or O-heteroaryl.

Printed circuit boards (“PCB”) that are more environmentally friendly than circuit boards using brominated BPA epoxy resins, as well as methods of making the PCBs, are provided herein. The PCBs include a cellulosic polymer having boronate moieties. Such materials are, alternatively, thermoset or thermoplastic materials that allow for forming of the material into a variety of shapes and sizes. Thermoset materials are obtained by boronating cellulose to a minimal extent e.g., by boronating less than about 40% of the hydroxyl groups of the cellulose polymer. Alternatively, thermoplastic resins are obtained by boronating at least about 40% of the hydroxyl groups of the cellulose polymer. In certain embodiments, thermoplastic resins are obtained by boronating about 40% to about 60% of the hydroxyl groups of the cellulose polymer. The thermoplastic resins may also be processed as liquids or used to impregnate other materials, including thermoset materials. Modification of cellulose with the boronate moieties reduces the flammability of the cellulose, and such materials tend to be less corrosive than traditional brominated BPA epoxy resins. The materials are also amenable to water-based processing which may provided advantages for the processing of wastes generated either during formation, or wastes associated with the discarding or recycling of an electronic device incorporating a PCB of the boronated cellulose. Overall, such boronated cellulose materials provide a more environmentally benign option in comparison to traditional, brominated BPA epoxy resins. They may also provide cost-effectiveness, ease of dealing with waste streams, compostability, reduced toxicity, reduced pollution, freedom from halogens, flame resistance, and non-corrosiveness. In some embodiments, the PCBs described herein are free of brominated BPA epoxy resin.

Cellulose, a principal component of trees, shrubs, grasses, and other plants, is a naturally occurring polymer. Chemically, cellulose is a polysaccharide made of glucose monomers linked through 1,4-β glycoside bonds. Cellulose is a renewable resource that may also be made by polymerizing glucose or amylose groups. The glucose is naturally produced from carbon dioxide during the process of photosynthesis.

The term “glucose monomer,” as used herein, refers to a chemical moiety or derivative thereof having the formula:

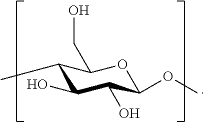

In its native form, cellulose is a pseudo-thermoset polymer, due to extensive hydrogen bonding between the polymer chains to prevent melting and flow of the polymer. As used herein, a “thermoset” (or “thermosetting plastic”) is polymer material that is irreversibly cured. For example, a thermosetting polymer may be a pre-polymer in a soft solid or viscous state that changes irreversibly into an infusible, insoluble polymer network upon curing. Curing can be by induced heat (generally above 200° C.), through a chemical reaction (e.g., a two-part epoxy), or irradiation (e.g., electron beam processing), or both. Once hardened, thermoset resins can not be reheated and melted back into a liquid form and, thus, thermoset polymers are not amenable to heating and reforming. A “pseudo-thermoset polymer” may be formable by mild heat and pressure. Psuedo-thermoset polymers generally exhibit some of the properties of a thermoset material, but may degrade upon heating before the polymer's glass transition temperature is reached.

“Thermoplastic polymers,” as used herein, are polymers that turn to a liquid when heated and solidify to a glassy state when sufficiently cooled. Thermoplastics are usually high-molecular-weight polymers whose chains associate with one another through weak Van der Waals forces, strong dipole-dipole interactions, hydrogen bonding, or it-stacking of aromatic rings. Unlike thermoset polymers, thermoplastic polymers are amenable to re-heating, re-melting, and/or re-molding.

As noted, the PCBs described herein include a cellulosic polymer having boronate moieties. Thus, the cellulose polymer is modified by reacting the cellulose with boron-containing compounds. In certain embodiments, the cellulose is minimally boronated and remains a psuedo-thermoset polymer. Alternatively, the cellulose is further boronated and becomes a thermoplastic polymer. The further boronation of the cellulose serves to disrupt, in particular, the hydrogen bonding of the cellulose to provide a boronated cellulose which has thermoplastic properties as opposed to its natural pseudo-thermoset properties.

The cellulose polymers that are to be boronated may be either natural or synthetic. When natural, suitable sources of the cellulosic polymer include, but are not limited to, paper, wood, cotton, cloth, fabric, parchment, hanji, washi, hemp, bamboo, rice, or starch.

Upon boronation, the boronated cellulosic polymers may have various chemical structures, depending on the chemical constituents present in the polymers. For example, the boronated cellulosic polymer can include glucose monomers as represented by one or more of Formulas I, II, III, IV, V, VI, or VII:

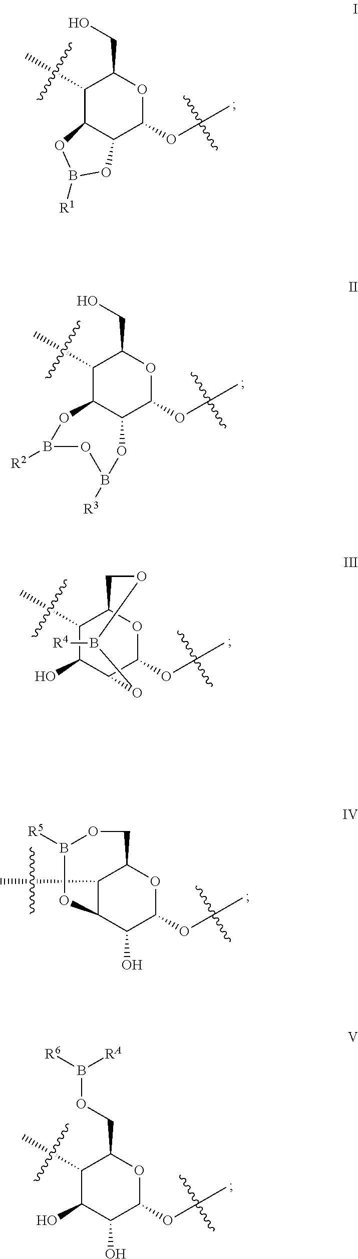

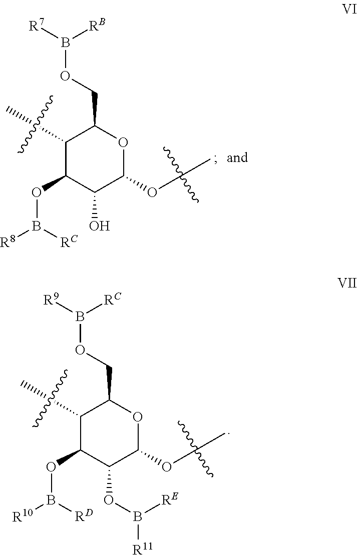

In Formula I, II, III, IV, V, VI, or VII, R¹-R¹¹ are each independently alkyl, alkenyl, cycloalkyl, heterocycloalkyl, aryl or heteroaryl; and where R^{A}-R^{E} are each independently OH, O-alkyl, O-alkenyl, O-aryl or O-heteroaryl. For example, R¹-R¹¹ are each independently C₁-C₈ alkyl, C₁-C₈ alkenyl, C₆ aryl, or C₅-C₁₀ heteroaryl. In some embodiments, R¹-R¹¹ are each independently methyl, ethyl, n-propyl, iso-propyl, n-butyl, iso-butyl, tert-butyl, ethenyl, propenyl, 1-butenyl, 2-butenyl, phenyl, tolyl, furan-2-yl, thiophen-2-yl, bromomethyl, bromoethyl, chloromethyl, chloroethyl, iodomethyl, iodoethyl, chlorobromomethyl, chlorobromoethyl, methylsulfanylmethyl, or methyl mercaptan. In some embodiments, R^{A}-R^{E} are each OH. In other embodiments, at least 20% of the glucose monomers of the cellulosic polymer include a glucose monomer of Formula I, II, III, IV, V, VI, or VII. In some embodiments, the boronated cellulosic polymer further comprising a solvent, inorganic filler, thermosettable resin, etchable synthetic rubber polymer, or a combination thereof.

In some embodiments, thermoset materials are obtained by boronating cellulose to a minimal extent e.g., by boronating less than about 40% of the hydroxyl groups of the cellulose polymer. In other embodiments, thermoplastic resins are obtained by boronating at least about 40% of the hydroxyl groups of the cellulose polymer. In certain embodiments, thermoplastic resins are obtained by boronating about 40% to about 60% of the hydroxyl groups of the cellulose polymer. In other embodiments, thermoplastic resins are obtained by boronating at least about 60% of the hydroxyl groups of the cellulose polymer.

Some of the glucose monomers of the native or synthetic cellulose may not be reacted with the boron compound. In some embodiments, the boronated cellulosic polymer has from about 1% to about 80% of its glucose monomers boronated. In other embodiments, the boronated cellulosic polymer has from about 1% to about 20% of its glucose monomers boronated. In some embodiments, the boronated cellulosic polymer has from about 40% to about 60% of its glucose monomers boronated. In some embodiments, the cellulosic polymer has at least about 60% of its glucose monomers boronated. In certain embodiments, less than 50% of the glucose monomers of the cellulose polymer comprise a glucose monomer of Formula I, II, III, IV, V, VI, or VII, or a combination of any two or more thereof. In some embodiments, at least 50% of the glucose monomers of the cellulose polymer comprise a glucose monomer of Formula I, II, III, IV, V, VI, or VII, or a combination of any two or more thereof. In other embodiments, from about 20% to about 60% of the glucose monomers include at least one boronated glucose moiety as represented by one or more of Formula I, II, III, IV, V, VI, or VII. In other embodiments, from about 20% to about 40% of the glucose monomers include at least one boronated glucose moiety as represented by one or more of Formula I, II, III, IV, V, VI, or VII. In other embodiments, from about 20% to about 30% of the glucose monomers include at least one boronated glucose moiety as represented by one or more of Formula I, II, III, IV, V, VI, or VII.

In some embodiments, the boronated cellulose polymer includes from about 1 wt % to about 200 wt % of an organoboron substituent of Formula VIII:

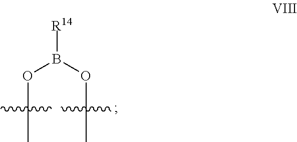

where R¹⁴ is alkyl, alkenyl, aryl, or heteroaryl. In some embodiments, the boronated cellulose polymer includes about 1 wt % to about 100 wt % of the organo-boron substituent. In some embodiments, the boronated cellulose polymer includes about 1 wt % to about 30 wt % of the organo-boron substituent. In some embodiments, the boronated cellulose polymer includes about 1 wt % to about 10 wt % of the organo-boron substituent. In some embodiments, the boronated cellulose polymer includes about 10 wt % to about 50 wt % of the organo-boron substituent. In some embodiments, the boronated cellulose polymer includes about 10 wt % to about 25 wt % of the organo-boron substituent.

The boronation of the cellulose to form cellulosic polymers having one or more glucose monomers of Formula I-VII, may be conducted by reacting the cellulose with a compound of Formula B(R)(OH)₂, B(R)(OR)₂, or (R₃BO)₃ where each R is individually R¹-R¹¹ as described above. Thus, upon reaction with the cellulose, a condensation reaction occurs thereby bonding the boron atom to the cellulose, through one or two oxygen atom(s). Complete reaction of two oxygen atoms in the B(R)(OH)₂, B(R)(OR)₂, or (R₃BO)₃ compounds, or at all glucose hydroxyl substituents in the cellulose may not occur, thereby leading to the variety of structures such as those described by Formulas I-VII.

Accordingly, in another aspect a method of preparing a boronated cellulosic polymer is provided. The method including reacting a cellulose polymer with a boron compound represented by Formula B(R)(OH)₂, B(R)(OR)₂, or (R₃BO)₃ where each R is individually R¹-R¹¹ as described above. The reacting may include the reaction of the boron compound with the polymer at ambient or elevated temperature, and may or may not include the use of a basic or acidic catalyst. The reaction may be conducted by suspending the cellulose polymer in a solvent and adding the boron compound. In some embodiments, the reaction is conducted at elevated temperature in a solvent that forms an azeotrope with water, thereby facilitating removal of the water a reflux temperatures. Suitable solvents include, but are not limited to, toluene, benzene, dimethyl sulfoxide, and dimethylformamide. Suitable acid catalysts may include, but are not limited to, p-toluenesulfonic acid, citric acid, acetic acid, boric acid, HCl, HBr, H₂SO₄, trifluoroacetic acid, methanesulfonic acid, phosphoric acid, nitric acid, or a Lewis acid such as aluminum halide, boron halide or a ferric halide catalyst. Suitable base catalysts may include, but are not limited to, diisopropylethylamine (DIPEA), triethylamine, piperidine, pyridine, 1,4-diazo-bicyclo[2.2.2]octane, N-methyl morpholine, tetramethyl butane diamine, and bis(2-dimethyl amino ethyl) ether.

The boronated cellulosic polymers may be in the form of minimally boronated fibers or as a more substantially boronated resin. Both the fibrous or resin forms may be used to form fire retardant PCBs. For example, the cellulose polymer fibers in paper products can be minimally boronated in their paper form to maintain the fiber structure (e.g., less than 40% of the hydroxyl groups of the cellulose polymer include a boronate moiety). As noted, for such an embodiment, the degree of boronation of the cellulose is minimal. For example, the boronated cellulosic polymer may have boronated approximately 40% or less of hydroxyl groups of the cellulose polymer. Alternatively, the boronated cellulosic polymer may have boronated approximately 20% or less of hydroxyl groups of the cellulose polymer.

Alternatively, the cellulose polymer can be highly boronated (e.g., at least about 40% of the hydroxyl groups of the cellulose polymer include a boronate moiety), thereby forming a highly boronated cellulosic polymer resin. For such an embodiment, the extent of the boronation of the cellulose is increased. For example, the boronated cellulosic polymer may have boronated from about 40% to about 60% of the hydroxyl groups of the cellulose polymer. In some embodiments, where the boronated cellulosic polymer assumes a resin form, at least about 60% of the hydroxyl groups of the cellulose polymer are boronated.

The boronated cellulosic polymer resin acts as a flame retardant which can improve heat resistance and exhibit excellent adhesion strength and insulation reliability when applied to, or infused into, a printed circuit board. In certain embodiments, the boronated cellulosic polymer resin may be directly applied to a substrate, such as a printed circuit board or its component materials, without further additives. In other embodiments, the boronated cellulosic polymer resin may be diluted with a solvent and applied as a varnish to a printed circuit board or its component materials. This solvent is not limited to any particular type, for example, acetone, methyl-ethyl ketone, toluene, xylene, ethyl acetate, ethylenglycol monomethylether, N,N-dimethylformamide, methanol, ethanol and combinations thereof.

In one embodiment, a minimally boronated cellulosic paper (a paper that is boronated but retains the fibrous character of the paper) is impregnated with a more substantially boronated cellulosic resin or varnish that includes the resin. The resin and paper may then be cured to form a substrate for a PCB. PCBs prepared from such substrates are biodegradable, due to the biodegradable cellulosic polymer contained therein.

The boronated cellulosic polymer resin, or a varnish that includes the resin, can be applied to a printed circuit board or its component materials by various non-pressure techniques, including brushing, spraying, dipping, soaking, or steeping, roll coating, spin coating, curtain coating, slot coating and screen printing. Alternatively, the boronated cellulosic polymer resin, or a varnish thereof, can be impregnated under pressure into a printed circuit board or its component materials, and dried at elevated temperatures in an oven (e.g., from about 80° C. to about 200° C.). The solvent is preferably removed by evaporation. For example, the evaporation may be carried out under reduced pressure (e.g., the application of a vacuum), by flushing, or the solvent may be driven off at high temperature.

In some embodiments, the PCB is impregnated with a boronated cellulosic polymer resin that has been combined with an additional thermosettable resin known for use in preparing printed circuit substrates. Examples include phenol-formaldehyde, urea-formaldehyde, melamine-formaldehyde, modified methacrylic, polyester, and epoxy resins. In other embodiments, the boronated cellulosic polymer resin is combined with about 1 wt % to about 50 wt % synthetic rubber polymer or etchable synthetic rubber polymer solids. The terms “etchable synthetic rubber polymer” refers to those synthetic rubber compositions which in the substantially cured state are attacked by chemical etchant solutions. Such compositions are known, and include those compositions that are uniformly etchable as well as those known to be selectively etchable (these latter, when exposed to chemical etchants, are attacked in a non-uniform manner whereby pits and pores of microscopic size are formed in the surface).

Suitable selectively etchable rubber polymers are the acrylonitrile-butadiene-styrene terpolymers, acrylonitrile-butadiene copolymers (nitrile rubbers) and butadiene-styrene copolymers while suitable uniformly etchable rubber polymers are the butadiene rubber polymers and the neoprene rubber polymers.

Suitable chemical etchants are also generally known; examples are chromium trioxide in water, sulphuric-chromic and sulphuric-phosphoric acid mixtures and potassium dichromate in sulphuric acid.

An inorganic filler can be added to the boronated cellulosic polymer resin for the printed circuit boards according to a particular object of use. Any inorganic filler can be used without limitation, which may include, for example, various types of whiskers made of calcium carbonate, alumina, titanium oxide, mica, aluminum carbonate, aluminum hydrate, magnesium silicate, aluminum silicate, silica, glass fiber, boric acid aluminum, silicon carbide and the like. Further, several types of whiskers may be used in combination with their mixing ratios varied at discretion.

Depending on the specific process used to apply boronated cellulosic polymer to the paper for fiberboard, varying levels of penetration may be obtained. The paper or fiberboard may be penetrated by the boronated cellulosic polymer a depth from 1 μm to complete saturation throughout. In some embodiments, the boronated cellulosic polymer penetrates the paper or fiberboard on a gradient scale such that there is more boronated cellulosic polymer at a surface of the paper or fiberboard with diminishing amounts toward a central region of the sheet of paper or fiberboard. In some embodiments, the central region of the paper is void of the boronated cellulosic polymer, with the boronated cellulosic polymer penetrating a surface of the paper or fiberboard to a depth of 500 μm or less. In some embodiments, the boronated cellulosic polymer penetrates a surface of the paper or fiberboard to a depth of 100 μm or less. In some embodiments, there is minimal or negligible impregnation of the paper with the thermoplastic boronated cellulosic polymer. For example, the boronated cellulosic polymer is present substantially only on the surface of the cellulosic material.

Alternatively, the paper or fiberboard may be completely impregnated with the thermoplastic boronated cellulosic polymer. In some embodiments, a weight percentage of the boronated cellulosic resin in the paper or fiberboard is from about 0.001% to about 90%. In other embodiments, the weight percentage of the boronated cellulosic resin in the paper or fiberboard is from about 1% to about 50%. In other embodiments, the weight percentage of the boronated cellulosic resin in the paper or fiberboard is from about 1% to about 25%. In other embodiments, the weight percentage of the boronated cellulosic resin in the paper or fiberboard is from about 1% to about 10%. In some embodiments, the weight percentage of the boronated cellulosic resin in the paper or fiberboard is from about 1% to about 5%.

The printed circuit board or its component materials include cellulosic fibers or sheets that may further include one or more materials such as woven or non-woven fabric cloths, inorganic fibers made of glass, alumina, boron, silica-alumina glass, silicon carbonate, silicon nitride, zirconia, and the like.

In some embodiments, the PCB may have a first surface, a second surface, and an interior. The different portions of the PCB may contain different materials. For example, the first surface, second surface, or both the first surface and second surface, may contain portions of a cellulose polymer having a boronate moiety, while the interior contains a portion of the cellulose polymer that does not have a boronate moiety. This may be the result of boronation of a cellulose paper or cellulose fiberboard as a surface treatment, without saturation in order to maintain the fibrous form of the starting cellulose material.

Generally, a method of making an article is provided. The method includes providing a non-thermoplastic cellulosic material including a first boronate moiety; and contacting the non-thermoplastic cellulosic material with a thermoplastic cellulosic polymer including a second boronate moiety. In certain embodiments, the first and second boronate moiety are provided in glucose monomers of Formula I, II, III, IV, V, VI, or VII, as shown above. In certain embodiments, the non-thermoplastic cellulosic material comprises paper. In some embodiments, at least some of the non-thermoplastic cellulosic material is infused with the thermoplastic cellulosic polymer. In certain embodiments, the method further comprises heating and pressurizing the non-thermoplastic cellulosic material and the thermoplastic cellulosic polymer. In some embodiments, the method further comprises printing a metallic conductor onto a surface of the article to form a printed circuit board. In certain embodiments, the method further comprises fusing together a plurality of the articles to make a laminated structure printed circuit board.

In another embodiment, a method of making a printed circuit board (PCB) with a boronated cellulosic polymer is provided. A cellulose paper or cellulose fiberboard may be minimally boronated as described, or it may be impregnated with a substantially boronated cellulosic polymer resin. Alternatively, a cellulose paper or cellulose fiberboard may be both minimally boronated and impregnated with the substantially boronated cellulosic polymer resin, to form a substrate. Such substrates may then be printed with metallic conductors to form networks of conduits for electron transfer through the PCB. Holes may be incorporated for device attachment, i.e., transistors, diodes, processors, resistors, chips, etc. The multiple substrates may be layered or laminated together to form structures with multiple printed conductor layers interconnected to form complex PCB systems. Different printing techniques may be used. For example in one embodiment, the metallic conductors are printed using lithography. Metallic conductors may include, but are not limited to, silver, gold, copper, platinum, palladium nickel, iron, ruthenium, tungsten, and alloys thereof. In one embodiment, the metallic conductor includes copper. In some embodiments, the method further includes fusing together a plurality of the articles to make a laminated structure printed circuit board. In some embodiments, the infusing includes heating and pressurizing the first cellulosic material and the thermoplastic cellulosic material.

Any of the commonly known additive or subtractive methods may be used to affix a metallic conductor, such as copper, to a printed circuit board. For example, there are three common “subtractive” methods (methods that remove the metallic conductor, such as copper) from the printed circuit boards:

“Silk screen printing” uses etch-resistant inks to protect the copper foil. Subsequent etching removes the unwanted copper. Alternatively, the ink may be conductive, printed on a blank (non-conductive) board.

“Photoengraving” uses a photomask and developer to selectively remove a photoresist coating. The remaining photoresist protects the copper foil. Subsequent etching removes the unwanted copper. The photomask is usually prepared with a photoplotter from data produced by a technician using computer-aided manufacturing (CAM) software. Laser-printed transparencies (for low-resolution requirements) or direct laser imaging techniques (for high-resolution requirements) may be employed.

“Printed circuit board (PCB) milling” uses a two or three-axis mechanical milling system to mill away the copper foil from the substrate. A PCB milling machine (a ‘PCB prototyper’) receives commands from host software that control the position of the milling head in the x, y, and (if relevant) z axis.

“Additive” processes may also be used to affix a metallic conductor, such as copper, to a printed circuit board. The most common is the “semi-additive” process in which the unpatterned board has a thin layer of copper already on it. A reverse mask is then applied. (Unlike a subtractive process mask, this mask exposes those parts of the substrate that will eventually become the traces.) Additional copper is then plated onto the board in the unmasked areas. Copper may be plated to any desired weight. Tin-lead or other surface platings are then applied. The mask is stripped away and a brief etching step removes the now-exposed original copper laminate from the board, isolating the individual traces.

The present technology, thus generally described, will be understood more readily by reference to the following Examples, which are provided by way of illustration and are not intended to be limiting of the present technology.

### EXAMPLES

### Preparation of Boronated Cellulosic Fibers or Paper:

### Example 1

(See Boronic Acids. Edited by D. G. Hall, 2005 Wiley-VCH Verlag GmbH & Co., Ch. 1, p 17 & 79.) The following procedure is used to partially boronate cellulosic fibers or paper. Cellulose fibers or papers are submerged in toluene in a Dean-Stark apparatus or in a vessel under vacuum. Methyl boronic acid CH₃B(OH)₂ or trimethyl boroxine (CH₃BO)₃ is added to the toluene at 0.05:1 molar ratio (boronic acid/boroxine:glucose monomer units in the cellulose of the paper). p-Toluenesulfonic acid (approximately 0.5 wt %) is added as a catalyst to drive the reaction. The mixture is heated to reflux and the water removed under vacuum or via the Dean-Stark apparatus. Upon completion, partially boronated cellulosic fibers or papers are recovered having boronate moieties with the following structure:

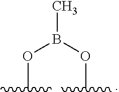 [SMILES: *OB(C)O* ; "."]

### Example 2

The following examples of partially boronated cellulosic fibers or papers are prepared by using the boronic acid or boroxine of column A in Table 1, below, according to methods substantially similar to those of Example 1. Upon completion, partially boronated cellulosic fibers or papers are recovered having boronate moieties with the structure in column B.

TABLE 1

| A | B |
|---|---|
| iso-Propyl boric acid (CH₃)CHB(OH)₂ or triisopropyl boroxine ((CH₃)CHBO)₃ | 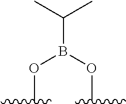 [SMILES: *OB(O*)C(C)C] |
| trans-Propenylboronic acid | 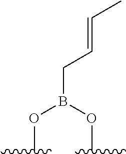 [SMILES: *OB(C/C=C/C)O*] |
| Phenylboronic acid | 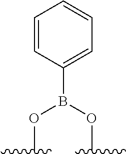 [SMILES: *OB(O*)c1ccccc1] |
| Thien-2-ylboronic acid | 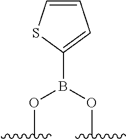 [SMILES: *OB(O*)c1cccs1] |

### Preparation of Boronated Cellulosic Resins.

### Example 3

The following procedure is used to substantially or fully boronate cellulosic fibers and produce resins. Cellulose fibers or particles are suspended in toluene in a Dean-Stark apparatus or in a vessel under vacuum similar to the method of Example 1. Methyl boronic acid CH₃B(OH)₂ or trimethyl boroxine (CH₃BO)₃ is added to the toluene in a molar ratio of about 0.5:1 to about 5:1 of boronic acid/boroxine:glucose monomer units in the cellulose of the fibers. p-Toluenesulfonic acid (approximately 0.5 wt %) is added as a catalyst to drive the reaction. The mixture is heated to reflux and the water removed under vacuum or via the Dean-Stark apparatus. Upon completion, a substantially or fully boronated cellulosic fiber resin is recovered having boronate moieties with the following structure:

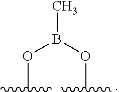 [SMILES: *OB(C)O* ; "."]

### Example 4

The examples shown above in Table 1 are prepared according to methods substantially similar to those of Example 3 to produce substantially or fully boronated cellulosic fiber resins. The boronic acid or boroxine of column A in Table 1 is used according to the methods of Example 3. Upon completion, a substantially or fully boronated cellulosic fiber resin is recovered having boronate moieties with the structure in column B.

Preparation of a Printed Circuit Board by Infusion of a Boronated Cellulosic Paper with a Boronated Cellulosic Resin.

### Example 5

Partially boronated cellulosic paper of Examples 1 or 2 can be infused with a boronated cellulosic resin of Examples 3 or 4 to yield printed circuit boards with improved flame retardant and adhesion properties. A partially boronated cellulosic paper of Examples 1 or 2 is coated with a varnish made of a solvent (e.g., toluene) and a boronated cellulosic resin of Examples 3 or 4. The paper is impregnated with the varnish under pressure (approximately 4.0 MPa or 4.07 kg/mm³) and heated and dried at 130° C. for approximately 5-10 minutes. A resin-impregnated paper sheet having a boronated cellulosic resin content of approximately 15 wt % is obtained. Circuit boards are made from two or more such paper sheets which are stacked and pressed under pressure of 4.0 MPa (4.07 kg/mm³) at 170° C. for 90 minutes. On the surface of the resulting circuit board is overlayed-copper-circuits or a copper foil of approximately 18 μm thick that can be etched into circuits according to methods known in the art. Chips, transistors, diodes, processors, resistors, and other components are added to complete the circuit board. The resulting circuit board has excellent flame retardant properties, but is less toxic than conventional circuit boards made from brominated bisphenol-A epoxy (BPA) resins.

### Equivalents

The embodiments, illustratively described herein may suitably be practiced in the absence of any element or elements, limitation or limitations, not specifically disclosed herein. Thus, for example, the terms ‘comprising,’ including, “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase ‘consisting essentially of’ will be understood to include those elements specifically recited and those additional elements that do not materially affect the basic and novel characteristics of the claimed technology. The phrase ‘consisting of’ excludes any element not specified.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent compositions, apparatuses, and methods within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as ‘up to,’ ‘at least,’ ‘greater than,’ ‘less than,’ and the like, include the number recited and refer to ranges which can be subsequently broken down into subranges as discussed above. Finally, as will be understood by one skilled in the art, a range includes each individual member.

While certain embodiments have been illustrated and described, it should be understood that changes and modifications can be made therein in accordance with ordinary skill in the art without departing from the technology in its broader aspects as defined in the following claims.

1. A printed circuit board comprising a cellulosic polymer comprising a boronate moiety wherein the cellulosic polymer comprises one or more glucose monomers of Formula I, II, III, IV, V, VI, or VII: 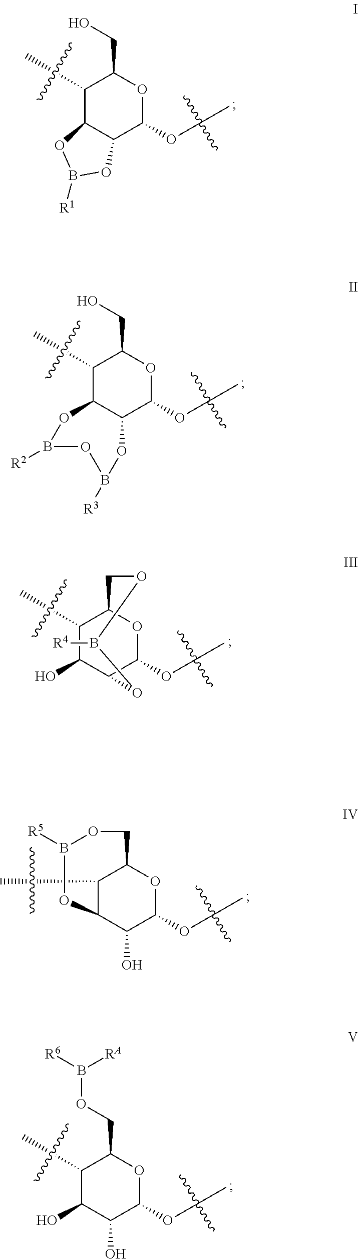 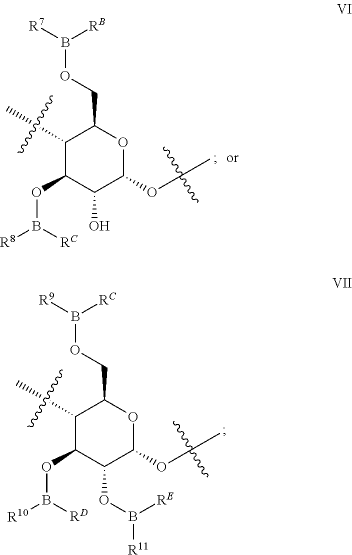
R¹, R², R³, R⁴, R⁵, R⁶, R⁷, R⁸, R⁹, R¹⁰, and R¹¹ are each independently alkyl, alkenyl, cycloalkyl, heterocycloalkyl, aryl, or heteroaryl; and
R^{A}, R^{B}, R^{C}, R^{D}, and R^{E} are each independently OH, O-alkyl, O-alkenyl, O-aryl or O-heteroaryl.

2. The printed circuit board of claim 1, wherein the cellulosic polymer comprises paper, cotton, cloth, fabric, parchment, hanji, washi, hemp, bamboo, rice, or starch.

3. The printed circuit board of claim 1, wherein the cellulosic polymer comprises a thermoplastic polymer.

4. (canceled)

5. The printed circuit board of claim 1, wherein R¹, R², R³, R⁴, R⁵, R⁶, R⁷, R⁸, R⁹, R¹⁰, and R¹¹ are each independently C₁-C₈ alkyl, C₁-C₈ alkenyl, C₆ aryl, or C₅-C₁₀ heteroaryl.

6. The printed circuit board of claim 5, wherein R¹, R², R³, R⁴, R⁵, R⁶, R⁷, R⁸, R⁹, R¹⁰, and R¹¹ are each independently methyl, ethyl, n-propyl, iso-propyl, n-butyl, iso-butyl, tert-butyl, ethenyl, propenyl, 1-butenyl, 2-butenyl, phenyl, tolyl, furan-2-yl, thiophen-2-yl, bromomethyl, bromoethyl, chloromethyl, chloroethyl, iodomethyl, iodoethyl, chlorobromomethyl, chlorobromoethyl, methylsulfanylmethyl, or methyl mercaptan.

7. The printed circuit board of claim 1, wherein R^{A}, R^{B}, R^{C}, R^{D}, and R^{E} are OH.

8. A printed circuit board comprising a cellulosic polymer comprising a boronate moiety, wherein the boronate moiety comprises about 1 wt % to about 30 wt % of a group of Formula VIII: 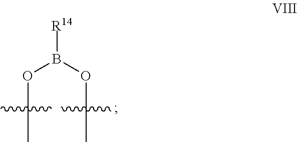
wherein
R¹⁴ is alkyl, alkenyl, aryl, or heteroaryl.

9. The printed circuit board of claim 8, comprising about 1 wt % to about 10 wt % of the groups of Formula VIII.

10. The printed circuit board of claim 1 having a first surface, a second surface, and an interior, wherein the first surface, second surface, or both the first surface and second surface, comprise the boronate moiety, and the interior does not comprise the boronate moiety.

11. The printed circuit board of claim 1, wherein the printed circuit board is free of a brominated BPA epoxy resin.

12-16. (canceled)

17. The printed circuit board of claim 1 which is biodegradable.

18. A composition comprising a cellulosic polymer having one or more glucose monomers of Formula I, II, III, IV, V, VI, or VII: 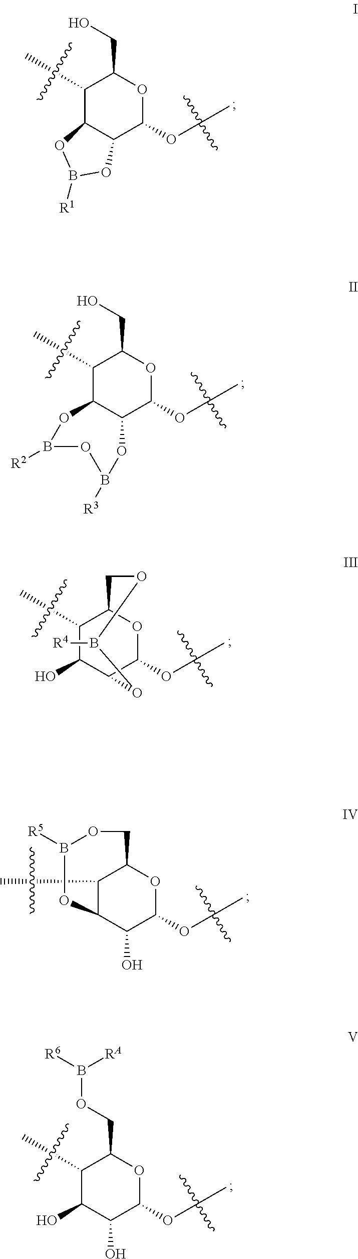 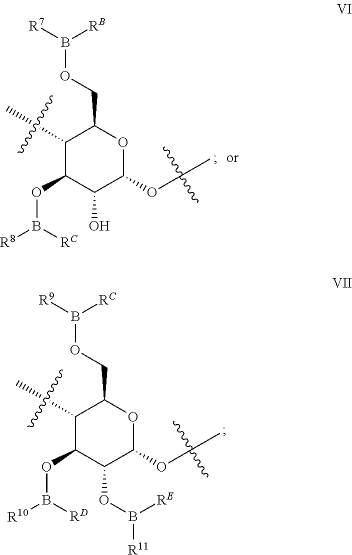
wherein
R¹, R², R³, R⁴, R⁵, R⁶, R⁷, R⁸, R⁹, R¹⁰, and R¹¹ are each independently alkyl, alkenyl, cycloalkyl, heterocycloalkyl, aryl, or heteroaryl;
R^{A}, R^{B}, R^{C}, R^{D}, and R^{E} are each independently OH, O-alkyl, O-alkenyl, O-aryl or O-heteroaryl; and
the composition is a resin.

19. The composition of claim 18, wherein R¹, R², R³, R⁴, R⁵, R⁶, R⁷, R⁸, R⁹, R¹⁰, and R¹¹ are each independently C₁-C₈ alkyl, C₁-C₈ alkenyl, C₆ aryl, or C₅-C₁₀ heteroaryl.

20. The composition of claim 19, wherein R¹, R², R³, R⁴, R⁵, R⁶, R⁷, R⁸, R⁹, R¹⁰, and R¹¹ are each independently methyl, ethyl, n-propyl, iso-propyl, n-butyl, iso-butyl, tert-butyl, ethenyl, propenyl, 1-butenyl, 2-butenyl, phenyl, tolyl, furan-2-yl, thiophen-2-yl, bromomethyl, bromoethyl, chloromethyl, chloroethyl, iodomethyl, iodoethyl, chlorobromomethyl, chlorobromoethyl, methylsulfanylmethyl, or methyl mercaptan.

21. The composition of claim 18, wherein R^{A}, R^{B}, R^{C}, R^{D}, and R^{E} are OH.

22. The composition of claim 18, further comprising a solvent, inorganic filler, thermosettable resin, etchable synthetic rubber polymer, or a combination thereof.

23-28. (canceled)
